(19) United States
(12) Patent Application Publication
(10) Pub. No.: US 2005/0281951 A1
(43) Pub. Date: Dec. 22, 2005

(54) Dielectric barrier discharge method for depositing film on substrates

(75) Inventor: Carmela C. Amato-Wierda, Durham, NH (US)

Correspondence Address: DEVINE, MILLIMET & BRANCH, P.A., 111 AMHERST STREET, BOX 719, MANCHESTER, NH, 03105, US

(73) Assignee: University of New Hampshire, Durham, NH (US)

(21) Appl. No.: 11/210,589

(22) Filed: Aug. 24, 2005

Related U.S. Application Data
(62) Division of application No. 10/229,309, filed on Aug. 27, 2002.
(60) Provisional application No. 60/315,098, filed on Aug. 27, 2001.

(51) Int. Cl. C23C 16/00

(52) U.S. Cl. 427/248.1

(57) ABSTRACT

A method of coating at least one wafer with film. The method includes first flowing at least one purge gas and at least one reactant gas at least partially through an activation space of at least one electrode set. Next, placing a wafer beneath the activation space of the at least one electrode set. Finally, supplying AC power to at least one electrode set whereby a dielectric barrier is discharged at least partially within the activation space, from which the film descends onto the wafer.

### RELATED APPLICATIONS

The present invention is a divisional of U.S. patent application Ser. No. 10/229,309, which was filed on Aug. 27, 2002 and claims the benefit of U.S. Provisional Patent Application Ser. No. 60/315,098, which was filed Aug. 27, 2001 incorporated herein by reference.

### COPYRIGHT

A portion of the disclosure of this patent document contains material which is subject to copyright protection. The copyright owner has no objection to the facsimile reproduction by anyone of the patent document or the patent disclosure as it appears in the United States Patent and Trademark Office patent file or records, but otherwise reserves all copyright rights whatsoever.

### FIELD OF THE INVENTION

The present invention relates to depositing thin films on substrates. Specifically, the present invention relates to the method for using a dielectric barrier discharge method for depositing film on substrates.

### BACKGROUND OF THE INVENTION

In silicon wafers intended for solar cell application, thin film deposited silicon nitride is used for cell passivation and as an antireflection coating. Films are deposited by any of a number of different means, including plasma enhanced chemical vapor deposition (“PECVD”). In a typical PECVD process for silicon nitride on solar cells, the silicon wafer is exposed to a plasma-excited gas composition derived from SiH₄ and NH₃. The PECVD process can be used to control the refractive index of the film-coated wafer and the hydrogen content of the film. One difficulty with this process is that it normally requires a vacuum chamber to provide a low-pressure atmosphere during plasma excitation and the use of a vacuum chamber substantially slows the production of solar cell wafers.

The photovoltaic industry uses the PECVD process to deposit silicon nitride film on silicon wafers. Typical equipment utilizes a parallel plate reactor to develop low-pressure plasma between the electrodes. Reactant gases, SiH₄ and NH₃, often mixed with inert dilute gases, flow in through a showerhead, which is also the top electrode. Plasma excitation is typically initiated using radio frequency power, which ranges from hundreds of kilohertz to thirteen megahertz, between the top electrode and the bottom electrode, on which the wafer sits. The proximity of the wafer to the electrical activity in this process can damage the wafer. This type of PECVD process is called direct PECVD because the wafer sits directly inside the plasma region.

The PECVD process has some variations. One variation of the PECVD process is called remote PECVD, as opposed to direct PECVD. Remote PECVD involves exposing only some of the gases directly to the plasma whereupon the plasma activated gases react to form the thin film of silicon nitride. The gases that are not exposed directly to the plasma will react with the activated gases. The remote PECVD process allows more control over the chemical reactions among gases involved, removes the wafer from any direct plasma exposure, and reduces the chance of wafer damage. However, the remote PECVD process is also typically operated below ambient pressure, requiring a vacuum chamber.

One of the main purposes of low-pressure operations is to stabilize the discharge plasma. Without the low-pressure environment, the discharge plasma cannot be sustained. A method of generating a thin film of silicon nitride at ambient pressure is desirable to avoid the expenses and encumbrances of using a vacuum chamber.

Dielectric barrier discharge is currently being developed as an attractive method for industrial plasma process applications because it can be performed in ambient pressure, removing the necessity of a vacuum chamber. Dielectric barrier discharge has not yet been used in any commercialized thin film process for solar cells or semiconductors. Besides obviating the need for a vacuum chamber, the difference between traditional PECVD processes and the dielectric barrier discharge process is the dielectric barrier discharge process has the ability to use a wider range of frequencies and power. This ability in turn allows the dielectric barrier discharge process to have a large-scale, industrial adaptability whereas traditional PECVD processes have frequency and power limitations that economically limit commercial exploitation.

As the use of the dielectric barrier process to produce thin films is still being developed, some shortcomings continue to exist in the process. One of the shortcomings is the continued use of DC power or radio frequency power (RF power) to initiate plasma excitation. Use of DC power or RF power is a technique carried over from traditional low-pressure PECVD techniques. DC power and RF power are less effective in ambient pressure because the plasma can only be sustained in a very narrow set of conditions. This set of conditions is not suitable for industrial solar cell applications. Specifically, use of low power in the discharge process inhibits large-scale production, and thereby commercialization of the process, while use of high DC or RF power in the discharge process will extinguish the plasma and fail to properly produce the desired film. A discharge process is needed that can use sufficient power to satisfy production requirements of industry without extinguishing the plasma or otherwise inhibiting the dielectric barrier discharge process.

### SUMMARY OF THE INVENTION

One aspect of the present invention is a method of coating at least one wafer with a film. The method includes the following steps. First, flowing at least one purge gas and at least one reactant gas at least partially through an activation space of at least one electrode set. Next, placing a wafer beneath the activation space of at least one electrode set. Finally, supplying AC power to the electrode set. A dielectric barrier is discharged at least partially within the activation space, from which the film descends onto the wafer.

Some embodiments of this aspect of the invention include one or more of the following. Where the supplying step further includes the step of heating the wafer. The heating can include heating the wafer to approximately 400 degrees Celsius. In some embodiments, the dielectric barrier is an impermeable dielectric barrier.

Another aspect of the present invention includes a method of coating at least one wafer with a film. The method includes the following steps. First, assembling at least one electrode set, wherein each electrode set includes at least one impermeable dielectric barrier between a top electrode and a bottom electrode. Between the top electrode and the bottom electrode is an activation space. Next, flowing at least one purge gas and at least one reactant gas at least partially through the activation space of at least one electrode set. Next, placing a wafer at least partially beneath the activation space of at least one electrode set. Finally, supplying AC power to at least one electrode set. A dielectric barrier is discharged at least partially within the activation space from which the film descends onto the wafer.

Some embodiments of this aspect of the invention include one or more of the following. Where the electrode sets, gases and wafer are contained within a process chamber. Where an additional step of pumping the gases out of the chamber after discharge is included. Where the wafer is heated above ambient temperature. Where the wafer is heated to approximately 400 degrees Celsius. Where the AC power is supplied with a current frequency between about 1 kilohertz and 500 kilohertz. Where the bottom electrode is a conductive conveyor belt whereby a plurality of wafers are carried on the belt, through an assembly line to receive the film. Where the method includes the step of flushing the wafers with an inert gas curtain before and after the wafers are placed at least partially beneath the activation space. The method can also include cleaning the wafers with a dielectric barrier discharge process in an inert gas environment before the wafers are placed at least partially beneath the activation space. The assembling step can also include assembling a plurality of top electrodes, a plurality of dielectric barriers and a single bottom electrode. The single bottom electrode can be a metal conveyor belt. The method may also include the step of heating the wafers above ambient temperature. The method can also include supplying AC power results in an electric field formed within the activation space and where the electric field has an intensity between about 100 V/cm and 100 kV/cm. Finally, the film can be silicon nitride.

Another aspect of the present invention is a method of coating at least one wafer with a film. This method includes the following steps. First, flowing at least one purge gas and at least one reactant gas at least partially through an activation space of at least one electrode set. The electrode set includes at least one impermeable dielectric barrier between a top electrode and a bottom electrode. The bottom electrode is a conductive conveyor belt. Also, an activation space between the top electrode and the bottom electrode. The next step of this method is placing a wafer beneath the activation space. Finally, supplying AC power to the electrode set. A dielectric barrier is discharged at least partially within the activation space. From here, the film descends onto the wafer.

Some embodiments of this aspect of the present invention include one or more of the following. An additional step of flushing the wafer with an inert gas curtain before and after the wafer is placed beneath the activation space. Also, where the film is silicon nitride.

These aspects of the invention are not meant to be exclusive and other features, aspects, and advantages of the present invention will be readily apparent to those of ordinary skill in the art when read in conjunction with the following description, appended claims and accompanying drawings, all of which illustrate the principles of the technology, by way of example only.

### BRIEF DESCRIPTION OF THE DRAWINGS

These and other features and advantages of the present invention will be better understood by reading the following detailed description, taken together with the drawings wherein:

FIG. 1 is a flow diagram of one embodiment of the method characterizing the present invention;

FIG. 2 is a flow diagram of one embodiment of the method characterizing the present invention;

FIG. 3 is an apparatus for performing a batch-operation, wafer-deposition process in accordance with one embodiment of the present invention;

FIG. 4 is an apparatus for performing a continuous-production, wafer-deposition process in accordance with one embodiment of the present invention; and

FIG. 5 is an apparatus for performing a wafer-deposition process in accordance with another embodiment of the present invention.

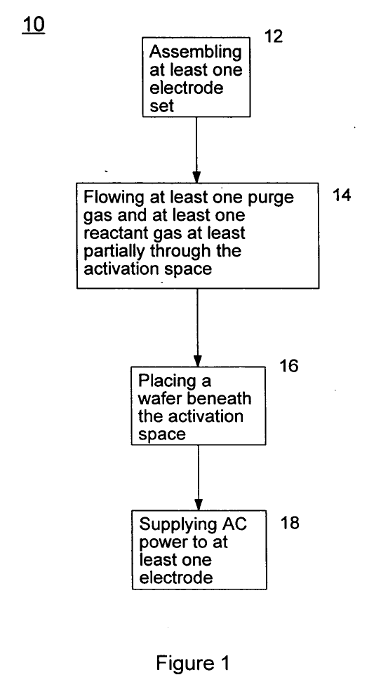

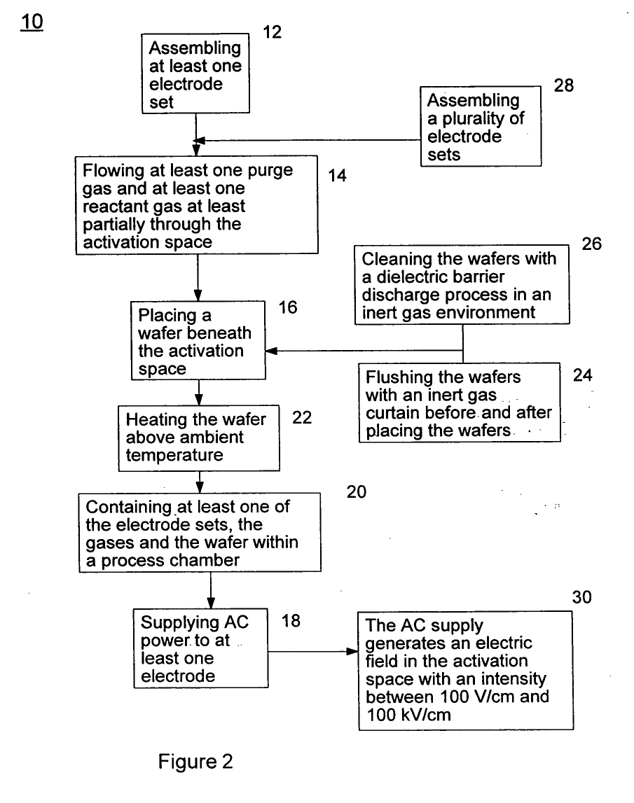

### DETAILED DESCRIPTION OF THE INVENTION

In one embodiment, the present invention is a method 10 of coating at least one wafer with a film. The first step in the method 10 is assembling 12 at least one electrode set. Each electrode set includes at least one impermeable dielectric barrier and an activation space between a top electrode and a bottom electrode. The second step is flowing 14 at least one purge gas and at least one reactant gas at least partially through the activation space of at least one electrode set, substantially at atmospheric pressure. The next step in the inventive method 10 is placing 16 a wafer beneath the activation space of at least one electrode set. The last step in this embodiment of the inventive method 10 is supplying 18 AC power to at least one electrode set thereby causing a dielectric barrier discharge at least partially within the activation space from which the film descends onto the wafer.

As described, this embodiment of the invention uses an impermeable dielectric barrier. A dielectric barrier is a nonconductor of direct electric current. Some existing art in the field of the present inventive method 10 use a dielectric barrier with a plurality of apertures, essentially spacing conductive channels for creating a glow discharge. The present inventive method uses a dielectric barrier without apertures or channels or any other means for the passage of direct current, which is herein defined as an impermeable dielectric barrier.

The inventive method 10 has several narrower embodiments. One narrower embodiment includes containing 20 at least one of the electrode sets, the gases and the wafer within a process chamber. A narrower embodiment of this design would include an exit pump for pumping the gases out of the chamber after discharge.

Another narrow embodiment of the inventive method 10 involves heating 22 the wafer above ambient temperature. Heating the wafer during the coating process increases the adhesiveness of the coating to the wafer. In a narrower embodiment, the wafer is heated to approximately 400 degrees Celsius during the dielectric barrier discharge process, as this wafer temperature has been determined to be ideal for the coating process.

Another narrow embodiment of the inventive method 10 involves supplying 18 the AC power with a frequency between 1 kilohertz and 500 kilohertz, a frequency well below that utilized by glow discharge.

Another narrow embodiment of the inventive method 10 involves making the bottom electrode a conductive conveyor belt whereupon multiple wafers are carried on the belt, through an assembly line, to receive the silicon nitride coating. A narrower embodiment of this design involves flushing 24 the wafers with an inert gas curtain before and after the wafers are placed between the electrodes, thereby cleaning the wafer. Alternatively, cleaning 26 the wafers is accomplished with a dielectric barrier discharge process in an inert gas environment before the wafers are placed between the electrodes. The conveyor belt embodiment may result in assembling 28 a plurality of electrode sets, wherein the plurality of electrode sets include a plurality of top electrodes, a plurality of impermeable dielectric barriers and a single bottom electrode, said single bottom electrode comprising a metal conveyor belt. In one embodiment, the conveyor belt embodiment includes heating 22 the wafers above ambient temperature. Finally, in one embodiment, the AC supply generates 30 an electric field in the activation space with an intensity between 100 V/cm and 100 kV/cm, which is believed to be at least one magnitude greater than the fields currently achieved through glow discharge.

The present invention may also be described as an apparatus 50 for coating a substrate 52 with a film. The apparatus 50 includes at least one top electrode 54, at least one bottom electrode 56 located below the top electrode 54, wherein an activation space 57 resides substantially between the top electrode 54 and the bottom electrode 56, and at least one impermeable dielectric barrier 58 located between the electrodes 54, 56. The apparatus 50 further includes at least one substrate seat 59 for supporting the substrate 52 in a substantially horizontal position beneath the activation space 57. Also, the apparatus 50 includes at least one purge gas 60 and at least one reactant gas 62 flowing at least partially within the activation space 57 at approximately atmospheric pressure. Finally, an AC power supply 64 is connected to at least one electrode 54, 56 whereby a dielectric barrier discharge will be caused within the activation space 57.

The inventive apparatus 50 may further include a process chamber 66 at least partially containing the electrodes 54, 56, the wafer seat 59, the dielectric barrier 58 and the gases 60, 62. The chamber 66 is maintained at atmospheric pressure or, more specifically, no specific effort is made to affect the pressure within the chamber 66 (i.e. utilizing a vacuum chamber). The central purpose of the chamber is to keep the gases 60, 62 contained between the electrodes 54, 56 and keep out other gases that would contaminate the dielectric barrier discharge process. The process chamber 66 may further include an intake pumping means 68 for pumping the gases 60, 62 into the chamber 66 and an exit pumping means 70 for pumping the gases 60, 62 out of the chamber 66.

In a narrower embodiment, the inventive apparatus 50 may include a heat source 72 for heating the substrate 52. The heat source 72 may further include a temperature sensor 74 and heat source power 76 controller whereby the temperature of the substrate 52 is definitively controlled.

Another narrower embodiment of the apparatus 50 involves the AC power supply 64 being maintained with a current frequency between about 1 kilohertz and about 500 kilohertz. This current frequency is well below the typical current frequency for glow discharge deposition apparatuses. While AC supply in some fields is understood to mean a frequency between 25 and 60 hertz, the present context only defines an AC power supply as a power supply with an alternating current.

Another narrower embodiment of the inventive apparatus 50 involves making the bottom electrode 56 a conductive conveyor belt 78 whereby multiple wafers 52 are carried on the belt 78, through an assembly line to receive the silicon nitride coating. This embodiment is further narrowed by adding an inert gas curtain 80 at a beginning 82 and an end 84 of the belt 78 thereby cleaning the wafers 52. Alternatively, this embodiment is further narrowed by having the electrodes 54, 56 and impermeable dielectric barriers 58 include a plurality of electrode sets 86, wherein an electrode set 86 include one top electrode 54, at least one impermeable dielectric barrier 58 and a shared bottom electrode 56, said shared bottom electrode 56 comprising a metal conveyor belt 78. This embodiment is further narrowed by having beginning electrode sets 86 at a beginning 82 of the belt 78 and middle electrode sets 86 at a middle 92 of the belt 78, wherein the beginning electrode sets 86 are substantially encompassed by an inert gas and the middle electrode sets 86 are substantially encompassed by the flowing purge and reactant gases 60, 62.

Finally, in one embodiment, the activation space 57 further includes an electric field. The electric field will have an intensity between 100 V/cm and 100 kV/cm, which is at least one magnitude greater than normally achieved by the glow discharge process.

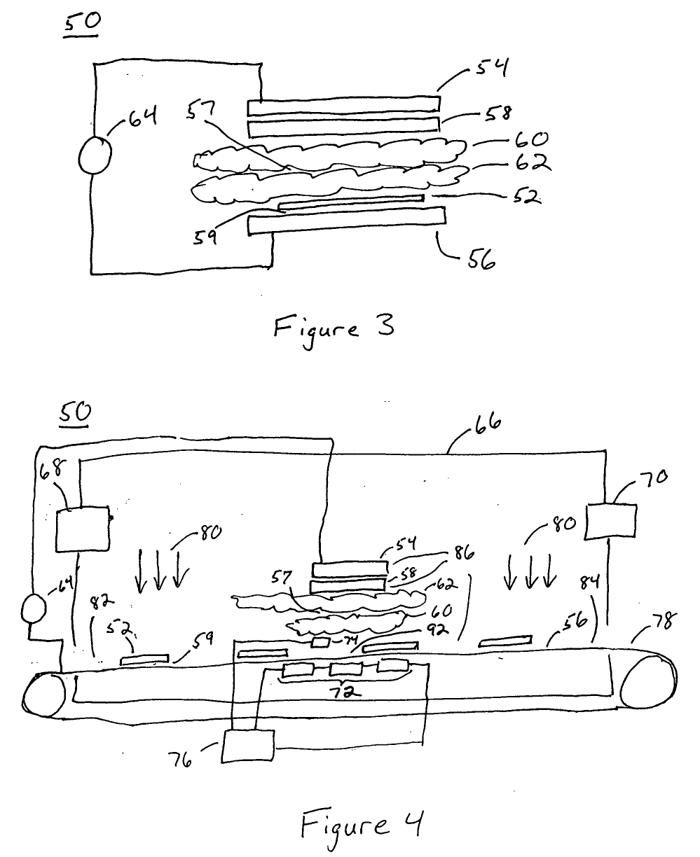

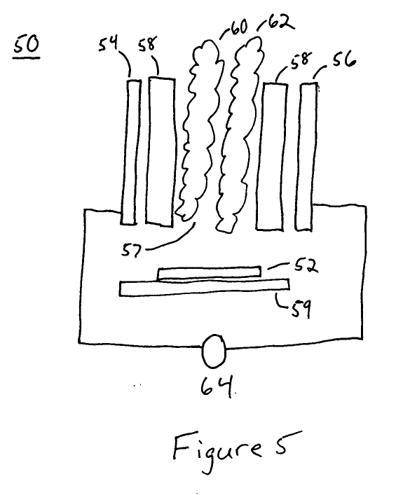

As described, the inventive method 10 and apparatus 50 can utilize either direct or remote dielectric barrier discharge. FIGS. 3 and 4 show one embodiment of direct dielectric barrier discharge while FIG. 5 shows one embodiment of remote dielectric barrier discharge. The main difference between the two discharge systems is the location of the wafer 52 in relation to the activation space 57. In both systems, the wafer 52 is at least partially below the activation space 57. However, in the direct dielectric barrier discharge system, the wafer 57 is partially within the activation space 57, between the horizontally placed electrodes 54, 56. In the remote dielectric barrier discharge system, the wafer 52 rests below the activation space 57, which is between the vertically-placed electrodes 54, 56.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

1. A method of coating at least one wafer with a film, said method comprising the steps of:
assembling at least one electrode set, wherein each electrode set includes at least one impermeable dielectric barrier between a top electrode and a bottom electrode, wherein between the top electrode and the bottom electrode is an activation space;
flowing at least one purge gas and at least one reactant gas at least partially through said activation space of at least one electrode set;
placing a wafer at least partially beneath said activation space of at least one electrode set; and
supplying AC power to at least one electrode set whereby a dielectric barrier is discharged at least partially within said activation space from which said film descends onto said wafer.

2. The method of claim 1 wherein said at least one of said electrode sets, said gases and said wafer are contained within a process chamber.

3. The method of claim 2 further comprising the step of pumping said gases into said chamber.

4. The method of claim 3 further comprising the step of pumping said gases out of said chamber after discharge.

5. The method of claim 1 further comprising heating said wafer above ambient temperature.

6. The method of claim 5 wherein said wafer is heated to approximately 400 degrees Celsius.

7. The method of claim 1 wherein said AC power is supplied with a current frequency between about 1 kilohertz and 500 kilohertz.

8. The method of claim 1 wherein said bottom electrode is a conductive conveyor belt whereby a plurality of wafers are carried on said belt, through an assembly line to receive said film.

9. The method of claim 8 further comprising the step of flushing said wafers with an inert gas curtain before and after said wafers are placed at least partially beneath said activation space.

10. The method of claim 8 further comprising cleaning said wafers with a dielectric barrier discharge process in an inert gas environment before said wafers are placed at least partially beneath said activation space.

11. The method of claim 8 wherein said assembling further comprising assembling a plurality of top electrodes, a plurality of dielectric barriers and a single bottom electrode, wherein said single bottom electrode comprising a metal conveyor belt.

12. The method of claim 8 further comprising the step of heating said wafers above ambient temperature.

13. The method of claim 1 wherein said step of supplying AC power results in an electric field formed within said activation space and wherein said electric field has an intensity between about 100 V/cm and 100 kV/cm.

14. The method of claim 1 wherein said film is silicon nitride.

15. A method of coating at least one wafer with a film, said method comprising the steps of:
flowing at least one purge gas and at least one reactant gas at least partially through an activation space of at least one electrode set;
placing a wafer beneath said activation space of said at least one electrode set; and
supplying AC power to said at least one electrode set whereby a dielectric barrier is discharged at least partially within said activation space from which said film descends onto said wafer.

16. The method of claim 15 wherein said supplying step further comprising the step of heating said wafer.

17. The method of claim 16 wherein said heating comprising heating said wafer to approximately 400 degrees Celsius.

18. The method of claim 15 wherein said dielectric barrier is an impermeable dielectric barrier.

19. A method of coating at least one wafer with a film, said method comprising the steps of:
flowing at least one purge gas and at least one reactant gas at least partially through an activation space of at least one electrode set, said electrode set comprising:
at least one impermeable dielectric barrier between a top electrode and a bottom electrode, said bottom electrode being a conductive conveyor belt; and
an activation space between said top electrode and said bottom electrode;
placing a wafer beneath said activation space of said at least one electrode set; and
supplying AC power to said at least one electrode set whereby a dielectric barrier is discharged at least partially within said activation space from which said film descends onto said wafer.

20. The method of claim 19 further comprising the step of flushing said wafer with an inert gas curtain before and after said wafer is placed beneath said activation space.

21. The method of claim 19 wherein said film is silicon nitride.
